(19) United States
(12) Patent Application Publication
(10) Pub. No.: US 2019/0189860 A1
(43) Pub. Date: Jun. 20, 2019

(54) ELECTRONIC CIRCUIT PACKAGE COVER

(71) Applicant: STMICROELECTRONICS (GRENOBLE 2) SAS, Grenoble (FR)

(72) Inventors: Jean-Michel RIVIERE, Froges (FR); Romain COFFY, Voiron (FR); Karine SAXOD, Les Marches (FR)

(21) Appl. No.: 16/218,944

(22) Filed: Dec. 13, 2018

(30) Foreign Application Priority Data
Dec. 15, 2017 (FR) 1762274

(51) Int. Cl. H01L 33/48; H05K 5/03; H01L 31/18; H01L 31/12; H01L 31/0232; H01L 31/0203; H01L 33/00; H01L 33/58

(52) U.S. Cl. CPC H01L 33/483; H05K 5/03; H01L 31/18; H01L 33/58; H01L 31/02327; H01L 31/0203; H01L 33/005; H01L 31/12

(57) ABSTRACT

An electronic circuit including a cover crossed by an element and having a planar main inner surface.

### BACKGROUND

### Technical Field

The present disclosure generally relates to the field of electronic circuits, and more particularly to covers and methods for forming of covers for integrated circuit packages.

### Description of the Related Art

Certain electronic packages comprise an electronic chip housed in a package. Such a package often comprises a support portion having the chip affixed thereto, and a cover portion covering the chip.

When the electronic circuit is an optical signal transmit and/or receive circuit, such as a time-of-flight measurement proximity sensor, the electronic chip comprises optical signal transmit and receive regions. The cover then comprises, opposite the transmit/receive regions, elements transparent for the wavelengths of the optical signals, for example, made of glass, such as lenses.

Similarly, in various other types of electronic circuits, elements are positioned in the cover.

### BRIEF SUMMARY

One embodiment is directed to an electronic circuit, comprising a cover having an element extending therethrough and having a planar main inner surface.

According to an embodiment, said element is transparent, filtering, or comprises a lens.

According to an embodiment, the cover has a constant thickness.

According to an embodiment, said element has the same thickness as the cover.

According to an embodiment, the circuit comprises a support supporting a chip.

According to an embodiment, the circuit comprises a spacer between peripheral portions of the cover and of the support.

According to an embodiment, the spacer is attached to the cover by glue.

According to an embodiment, the spacer comprises a housing containing the glue.

An embodiment provides an optical transmission and/or reception circuit such as hereabove.

According to an embodiment, the optical transmission and/or reception circuit comprises an opaque partition of separation between optical transmission and/or reception regions of the circuit.

According to an embodiment, the spacer and the partition form a monoblock assembly.

According to an embodiment, the opaque partition is formed of a stack of beads of glue.

An embodiment provides a method of manufacturing a circuit such as hereabove.

According to an embodiment, the method comprises a step a) of manufacturing the cover by molding.

According to an embodiment, the molding is assisted by a film.

According to an embodiment, the method comprises, before step a), arranging said element on an adhesive film.

According to an embodiment, the method comprises a step b) of positioning the cover with respect to a chip of the circuit.

According to an embodiment, said element is transparent or filtering and is positioned at step b) relative to a guide mark on the chip by observing the guide mark through said element.

The foregoing and other features and advantages will be discussed in detail in the following non-limiting description of specific embodiments in connection with the accompanying drawings.

### BRIEF DESCRIPTION OF THE SEVERAL VIEWS OF THE DRAWINGS

FIG. 1 is a simplified cross-section view of an embodiment of an electronic circuit;

FIGS. 2A to 2D are simplified cross-section views illustrating an embodiment of a method of forming an electronic circuit cover;

FIGS. 3A and 3B are simplified views, respectively in cross-section and in top view, illustrating an embodiment of a sub-assembly of an electronic circuit package;

FIGS. 4A to 4C are simplified cross-section views illustrating an implementation mode of an electronic circuit forming method;

FIG. 5 is a partial simplified cross-section view of an alternative embodiment of the sub-assembly of FIGS. 3A and 3B;

FIGS. 6A and 6B are respective simplified cross-section and top views illustrating an embodiment of a sub-assembly of an electronic circuit package; and

FIGS. 7A and 7B are simplified cross-section views illustrating an implementation mode of an electronic circuit forming method.

### DETAILED DESCRIPTION

The same elements have been designated with the same reference numerals in the various drawings and, further, the various drawings are not to scale. For clarity, only those steps and elements which are useful to the understanding of the described embodiments have been shown and are detailed. In particular, the electronic chip and the package elements other than the cover are not detailed, the described embodiments being compatible with most current electronic packages and chips.

In the following description, when reference is made to terms qualifying absolute positions, such as terms “front,” “rear,” “top,” “bottom,” “left,” “right,” etc., or relative positions, such as terms “above,” “under,” “upper,” “lower,” etc., or to terms qualifying directions, such as terms “horizontal,” “vertical,” etc., it is referred to the orientation of the drawings, it being understood that, in practice, the described devices may be oriented differently. Unless otherwise specified, expressions “approximately,” “substantially,” and “in the order of” mean to within 10%, preferably to within 5%.

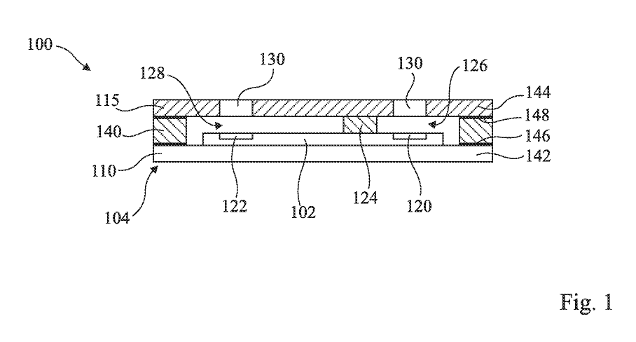

FIG. 1 is a cross-section view of an embodiment of an electronic circuit 100. Electronic circuit 100 comprises an electronic chip 102 housed in a package 104. The electronic chip 102 includes semiconductor material with one or more integrated circuits as is well known in the art.

Package 104 comprises a support 110 and a cover 115. Chip 102 is arranged on a central portion of support 110, in a closed space particularly delimited by support 110 and cover 115.

As an example, chip 102 comprises an optical transmission region 120 and an optical reception region 122. Optical transmission/reception regions 120 and 122 are for example separated by an opaque partition 124. Partition 124 thus separates the closed spaces or cavities delimited by the support and the cover into a transmit area 126 and a receive area 128. Optical transmission/reception regions 120 and 122 face transparent elements 130 extending through cover 115.

More generally, according to the type of electronic circuit, one or a plurality of elements of any type may be provided instead of the two transparent elements 130 of this example.

The main inner surface of cover 115, facing chip 102 and occupying the inner side of the cover, is planar. A planar surface here designates a surface which does not deviate by more than 10 μm, preferably 5μm, from a plane, over more than 90%, for example, more than 95%, of the inner side of the cover, preferably over the entire inner side of the cover. In particular, the planar surface does not have raised areas higher than 10 μm, preferably no raised areas higher than 5 μm. The planar surface is for example parallel to the main plane of the chip.

A spacer, for example, a frame 140, between peripheral portions 142 and 144 of support 110 and cover 115, mechanically connects the cover to the support. Frame 140 is for example thicker than chip 102, and chip 102 is thus located under the level of cover 115. Frame 140 is typically glued (glues 146 and 148) to the respective peripheral portions 142 and 144 of support 110 and of cover 115. As a variation, the spacer may be a portion of support 110, for example corresponding to raised peripheral portions of support 110.

The fact of providing a planar surface provides an accurate positioning of elements 130 in the cover, which enables to avoid, in the electronic circuit, problems of misalignment between chip 102 and elements 130.

As an example, cover 115 has the shape of a plate of constant thickness. The cover is here considered as having a constant thickness if it does not have, over for example more than 90%, for example, more than 95% of its surface, preferably over its entire surface, a thickness variation of more than for example 10%, preferably 5%. The thickness of elements 130 is for example in the range from 100 μm to 400 μm. As an example, cover 115 and elements 130 have a same constant thickness.

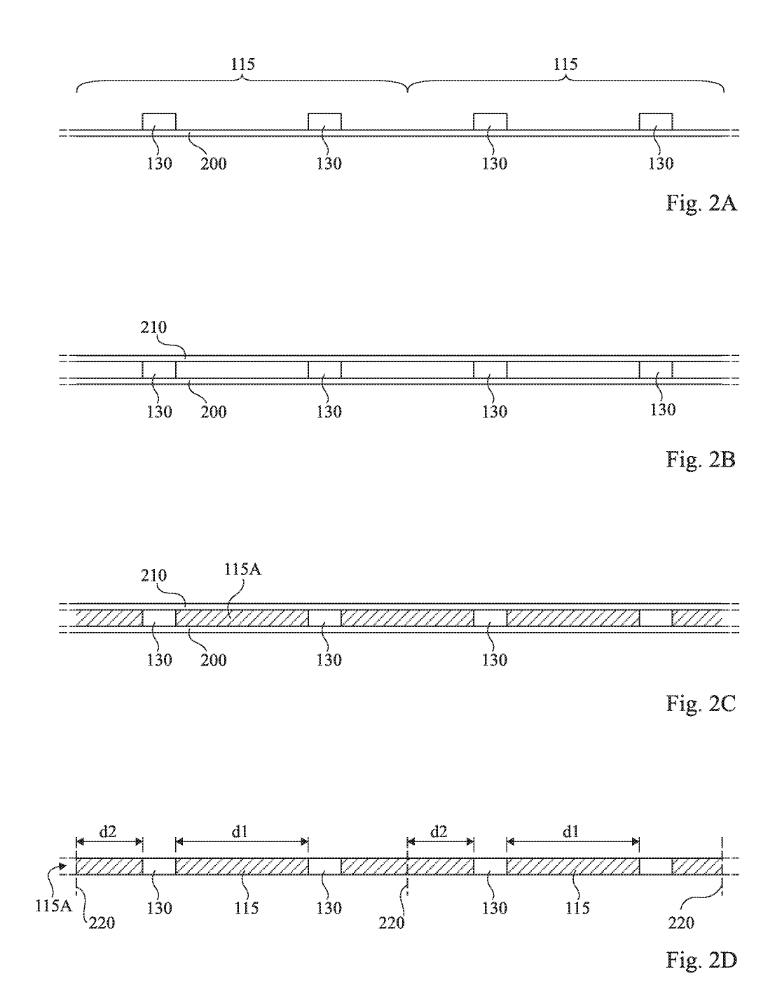

FIGS. 2A to 2D are simplified cross-section views illustrating an embodiment of a method of forming a cover 115 having elements 130 extending therethrough.

As an example, a plurality of covers 115 arranged in an array are simultaneously manufactured, and FIGS. 2A to 2D illustrate the manufacturing of two neighboring covers.

At the step of FIG. 2A, elements 130, for example, having a same thickness, are positioned on a planar surface of an adhesive support, for example, a first adhesive film 200. Adhesive film 200 is provided to maintain elements 130 in place in the rest of the process, and to be removed afterwards. As an example, adhesive film 200 is a polymer film, having a thickness for example in the range from 10 to 100 μm, covered with a layer of an adhesive allowing a temporary mechanical bonding. As an example, adhesives known under trade names “Lintec C-902” or “Nitto Revalpha” may be used.

At the step of FIG. 2B, elements 130 are covered with a second film 210. Film 210 rests on the upper surfaces of elements 130. Film 210 is not in contact with adhesive film 200 between elements 130. Film 210 for example remains parallel to the upper surface of adhesive film 200.

At the step of FIG. 2C, the entire structure obtained at the step of FIG. 2B is placed in a mold. Adhesive film 200 and film 210 are against inner surfaces of the mold, not shown, which are, for example, planar and parallel. A layer 115A, for example, of constant thickness, is formed by molding between the films. During the molding, the films rest on the surfaces of the mold. As an example, layer 115A is made of a thermosetting polymer.

At the step of FIG. 2D, adhesive film 200 and film 210 are removed, after which layer 115A is divided into individual covers 115, for example, by cutting along lines 220. In each of the obtained covers 115, the material of layer 115A bonds to the sides of elements 130, which maintains elements 130 in place in the cover. Each of the covers 115 thus obtained has a planar main surface, and preferably its two main surfaces are planar and parallel to each other.

The method of FIGS. 2A to 2D enables to obtain, in each cover 115, one or a plurality of accurate distances d1 between elements 130, with an accuracy better than for example in the order of 5μm. As an example, distances d1 are in the range from 0.5 mm to 5 mm. Distances d1 are accurately obtained despite the fact that, during the molding of the step of FIG. 2C, displacements of elements 130 may occur, for example, due to deformations of adhesive film 200. Such displacements particularly occur when layer 115A corresponds to several hundreds, or even several thousands, of covers 115. Such displacements affect entire regions of layer 115A in the same way, and neighboring elements 130 move together. Thereby, the values of distances d1 in covers 115 are the same as those obtained on installation of elements 130 at step 2A. As a result, distances d1 are accurately obtained even if distances d2 between elements 130 and cutting lines 220 may vary from one cover 115 to the other.

Although layer 115A has been formed by molding assisted by a film 210 at the step of FIG. 2B, as a variation, film 210 may be omitted.

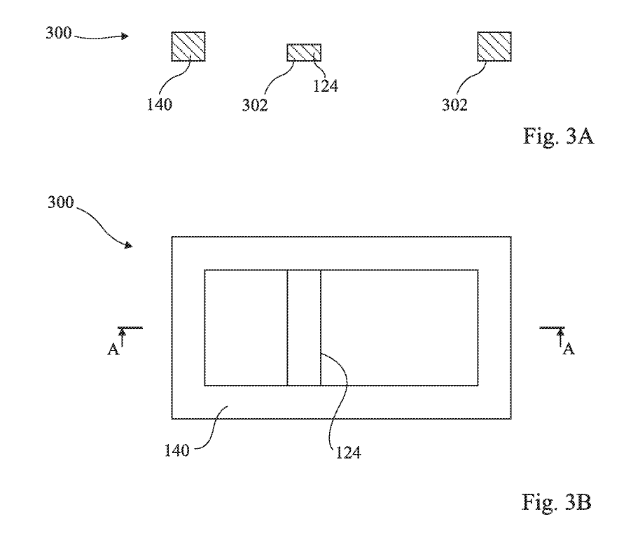

FIGS. 3A and 3B are simplified cross-section and top views and illustrate an embodiment of a sub-assembly 300 of an electronic circuit package. The cross-section plane of FIG. 3A is plane A-A shown in FIG. 3B.

Sub-assembly 300 comprises frame 140 and for example partition 124. Sub-assembly 300 is for example monoblock. Typically, sub-assembly 300 is formed by molding, for example of a thermosetting polymer, for example, the same polymer as that of layer 115A of FIG. 2C.

As an example, frame 140 has a planar main surface 302. Frame 140 may be rectangular, partition 124 connecting two opposite members of the frame. Partition 124 for example has a surface located in the plane of surface 302. For an optical electronic transmission and/or reception circuit, the material of sub-assembly 300 is preferably opaque to the wavelengths of the signals transmitted and received by the circuit.

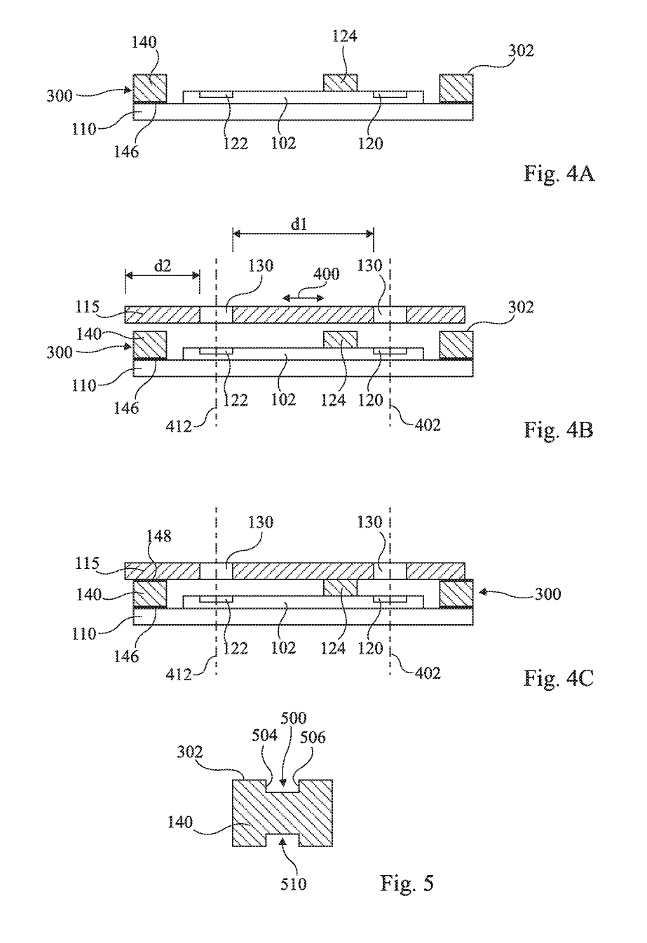

FIGS. 4A to 4C are simplified cross-section views of an embodiment of an electronic circuit forming method, for example, from a sub-assembly 300 of the type in FIGS. 3A and 3B and a cover 115 of the type obtained by the method of FIGS. 2A to 2D.

At the step of FIG. 4A, a chip 102, for example, an optical transmission/reception chip comprising optical transmission and reception regions 120, 122, is arranged on a central portion of a support 110. Frame 140 of sub-assembly 300 is mechanically bonded, for example, by glue 146, to peripheral portion 142 of support 110, so that partition 124 of sub-assembly 300 is located on the chip between regions 120 and 122. Planar surface 302 of sub-assembly 300 is located on the side opposite to support 110.

At the step of FIG. 4B, the planar surface of cover 115 is brought towards surface 302 of frame 140. Cover 115 is positioned relative to chip 102, for example, by a horizontal displacement 400 taking one of elements 130 to a position adjusted, along an axis 402, opposite an optical transmission or reception region 120. Cover 115 may if desired be rotationally adjusted to take another element 130 to a position adjusted along an axis 412.

Due to the fact that distances d1 between elements are accurate, all elements 130 can thus be accurately positioned. This is possible despite possible variations of distances d2 between elements 130 and the edges of cover 115, since the cover can be freely displaced in the horizontal direction. In this example, this possibility of freely displacing the cover in the horizontal direction results from the fact that the main surface of the cover facing the inside of the circuit is planar. Any other shape of the cover capable of enabling to horizontally displace the cover with respect to the support may be provided.

As an example, to take an element 130 to an accurate position, a guide mark has been provided on the chip, for example, an edge of an optical transmission component of the chip is used. The position of transparent element 130 is adjusted with respect to the guide mark by observing the guide mark through the transparent element. Any other known method enabling to adjust the position of element 130 may be used for this purpose, for example, by a laser or by optical observation.

As a variation, any type of element 130, specific to an electronic circuit, may be positioned relative to a chip of the electronic circuit positioned on a support 110, for example, by adjustment of the position of an accessible portion of element 130 relative to a guide mark accessible on support 110. An optical access to the guide marks may be provided for this purpose.

At the step of FIG. 4C, cover 115 is mechanically bonded to frame 140 of sub-assembly 300, for example, by glue 148, in the position obtained at the step of FIG. 4B. As an example, glue 148 is arranged before the step of FIG. 4B and the polymerization of glue 148 is carried out at the step of FIG. 4C. Partition 124 may be glued to the cover.

FIG. 5 is a partial simplified cross-section view of an example of a variation of frame 140 of sub-assembly 300 of FIGS. 3A and 3B.

Frame 140 has, on its surface intended to be glued to cover 115, a housing 500 intended to receive glue 148. As an example, housing 500 is a groove extending around surface 302 of the frame between two shoulders 504 and 506. As a variation, not shown, housing 500 is delimited by a single shoulder and emerges into the outer or inner edge of the frame. Similarly, frame 140 may have, on its surface intended to be glued to support 110, a housing 510 intended to receive glue 146. Housing 510 may be a groove or a housing delimited by a shoulder and emerging into the outer or inner edge of the frame.

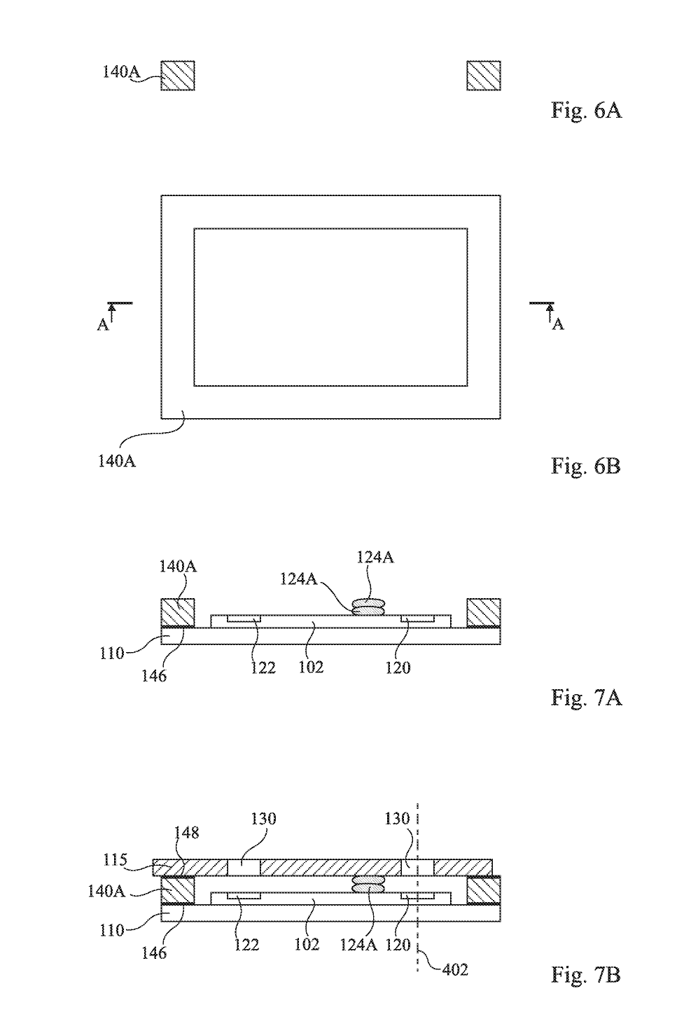

FIGS. 6A and 6B are simplified cross-section and top views illustrating an embodiment of a frame 140A of an electronic circuit package. Cross-section plane A-A of FIG. 6A is shown in FIG. 6B.

Frame 140A is identical to frame 140 of sub-assembly 300 of FIG. 3A, with the difference that frame 140A does not form a monoblock assembly with partition 124. In particular, the variation of frame 140 of FIG. 5 is compatible with frame 140A.

FIGS. 7A and 7B are simplified cross-section views illustrating an embodiment of a method of forming an electronic circuit, for example, from the frame of FIGS. 6A and 6B and covers 115 of the type obtained by the method of FIGS. 2A to 2D. The step of FIG. 7A corresponds to that of FIG. 4A, where, instead of partition 124, a bead of glue or a stack of beads of glue 124A is formed between transmission/reception regions 120 and 122 of the chip. As an example, each bead of glue 124A has a thickness in the range from 200 μm to 1 mm. As an example, the stack comprises 4 or more beads. Beads 124A are for example made of glue such as that known under trade name “Delo GE7985,” or of any other material intended to harden, for example, by polymerization, suitable to form a bead or stacked beads, preferably opaque after hardening.

At the step of FIG. 7B, steps similar to those of FIGS. 4B and 4C are successively implemented. A total thickness of the stack of beads 124A sufficient for cover 115 to press on the top of the stack on installation of the cover has been provided. The stack deforms. After the installation of the cover, the hardening of the bead material provides an opaque partition.

In the obtained electronic circuit, the opaque partition is thus formed of the stack of beads 124A. As a variation of the method of FIGS. 7A and 7B, the partition may be formed by any other adapted means.

Specific embodiments have been described. Various alterations, modifications, and improvements will occur to those skilled in the art. In particular, although examples applied to transparent elements 130 have been described, all the described embodiments more generally apply to any element housed in a cover for which the same problems are posed, particularly elements comprising lenses, for example, for focusing optical signals, or filtering elements enabling to remove all or part of optical radiations having wavelengths different from those of optical signals transmitted or received by the integrated circuit.

Finally, the practical implementation of the described embodiments is within the abilities of those skilled in the art based on the functional indications given hereabove.

Such alterations, modifications, and improvements are intended to be part of this disclosure, and are intended to be within the spirit and the scope of the present invention. The various embodiments described above can be combined to provide further embodiments. These and other changes can be made to the embodiments in light of the above-detailed description. Accordingly, the foregoing description is by way of example only and is not intended to be limiting. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic circuit comprising:
a cover having a planar inner surface and a through opening in the cover; and
a transparent element located in the through opening.

2. The circuit of claim 1, wherein the transparent element includes at least one of a filter or a lens.

3. The circuit of claim 1, wherein the cover has planar outer surface and a constant thickness between the planar inner surface and the planar outer surface.

4. The circuit of claim 3, wherein the transparent element has first and second opposing surfaces, wherein the first surface of the transparent element is coplanar with the planar inner surface of the cover and the second surface of the transparent element is coplanar with the planar outer surface of the cover.

5. The circuit of claim 1, further comprising a support supporting a semiconductor chip, the cover coupled to the support and covering the chip.

6. The circuit of claim 5, further comprising a spacer between peripheral portions of the cover and of the support.

7. The circuit of claim 6, wherein the spacer is attached to the cover and the support by glue.

8. The circuit of claim 7, wherein the spacer comprises a housing containing the glue.

9. An optical transmission and reception circuit, comprising:
a substrate;
a semiconductor chip coupled to the substrate;
a spacer coupled to the substrate; and
a cover coupled to the spacer and enclosing the semiconductor chip, the cover including:
a body having first and second planar surfaces; and
first and second transparent elements located in the body and extending between the first and second planar surfaces.

10. The circuit of claim 9, wherein the semiconductor chip includes an optical transmission region and an optical reception region, the circuit further comprising an opaque partition between the cover and the substrate that separates the optical transmission region from the optical reception region.

11. The circuit of claim 10, wherein the spacer and the opaque partition form a monoblock assembly.

12. The circuit of claim 10, wherein the opaque partition is formed of a stack of beads of glue.

13. A method comprising:
coupling a semiconductor chip to a surface of a substrate, the semiconductor chip including an optical transmitting region and an optical receiving region;
coupling a spacer to the substrate, the spacer being located around the semiconductor chip; and
coupling a cover to the spacer and enclosing the semiconductor chip, the cover including:
a body having first and second planar surfaces; and
first and second transparent elements located in the body and extending between the first and second planar surfaces, the first transparent element facing the optical transmitting region of the semiconductor chip and the second transparent element facing the optical receiving region of the semiconductor chip.

14. The method of claim 13, wherein prior to coupling the cover to the spacer, the method includes forming the cover.

15. The method of claim 14, wherein forming the cover includes forming the cover in a molding process that is assisted by a film.

16. The method of claim 14, wherein forming the cover includes placing the first and second transparent elements on an adhesive film and forming the body in a mold.

17. The method of claim 13, wherein the first and second transparent elements include a filter.

18. The method of claim 17, wherein coupling the cover to the spacer includes using a guide mark of the semiconductor chip by observing the guide mark through at least one of the first and second transparent elements.

19. The method of claim 13, further comprising coupling an opaque partition to a surface of the semiconductor chip between the optical transmitting region and the optical receiving region.

20. The method of claim 19, wherein coupling the opaque partition occurs simultaneously with coupling the coupling the spacer to the substrate.
